(19) United States
(12) Patent Application Publication
(10) Pub. No.: US 2026/0038608 A1
(43) Pub. Date: Feb. 5, 2026

(54) ADAPTIVE READ DISTURB SCAN FOR ASYMMETRIC BLOCKS

(71) Applicant: Micron Technology, Inc., Boise, ID (US)

(72) Inventors: Peng Zhang, Los Altos, CA (US); Murong Lang, San Jose, CA (US); Zhenming Zhou, San Jose, CA (US)

(21) Appl. No.: 18/791,177

(22) Filed: Jul. 31, 2024

(51) Int. Cl. G11C 16/34; G11C 16/08

(52) U.S. Cl. CPC G11C 16/3418; G11C 16/08

(57) ABSTRACT

A system comprises a memory device and a processing device, operatively coupled to the memory device. The processing device receives a request to perform a read disturb scan for a block of the memory device, wherein the block is partially programmed. The processing device determines the block is asymmetric, wherein the block comprises a plurality of sections, and wherein each section comprises memory cells corresponding to a different physical block in the memory device. Responsive to determining the block is asymmetric, the processing device identifies a target section of the block. The processing device executes the read disturb scan on an unprogrammed wordline of the target section.

### TECHNICAL FIELD

Embodiments of the disclosure relate generally to memory sub-systems, and more specifically, relate to an adaptive read disturb scan for asymmetric blocks.

### BACKGROUND

A memory sub-system can include one or more memory devices that store data. The memory devices can be, for example, non-volatile memory devices and volatile memory devices. In general, a host system can utilize a memory sub-system to store data at the memory devices and to retrieve data from the memory devices.

### BRIEF DESCRIPTION OF THE DRAWINGS

The disclosure will be understood more fully from the detailed description given below and from the accompanying drawings of various embodiments of the disclosure. The drawings, however, should not be taken to limit the disclosure to the specific embodiments, but are for explanation and understanding only.

FIG. 1 illustrates an example computing system that includes a memory sub-system in accordance with some embodiments of the present disclosure.

FIG. 2 is a flow diagram of an example method to perform an adaptive read disturb scan on a block, in accordance with some embodiments of the present disclosure.

FIG. 3A is a diagram illustrating a memory array of a bi-section memory device, in accordance with some embodiments, e.g., half-good block (HGB) programming.

FIG. 3B is a diagram illustrating a memory array of a multi-section memory device, in accordance with some embodiments, e.g., third-good block (TGB) programming.

FIG. 4 is a diagram illustrating an asymmetric block with a target section, in accordance with some embodiments of the present disclosure.

FIG. 5A-5C are example diagrams illustrating the identification of target sections in a block, in accordance with some embodiments of the present disclosure.

FIG. 6 is a block diagram of an example computer system in which embodiments of the present disclosure may operate.

### DETAILED DESCRIPTION

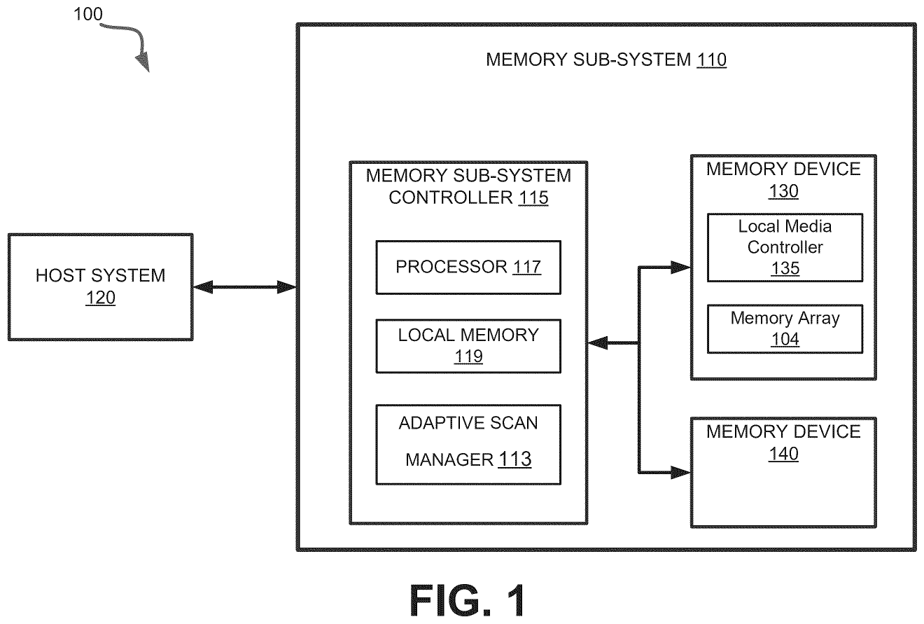

Aspects of the present disclosure are directed to an adaptive read disturb scan for asymmetric blocks. A memory sub-system can be a storage device, a memory module, or a combination of a storage device and memory module. Examples of storage devices and memory modules are described below in conjunction with FIG. 1. In general, a host system can utilize a memory sub-system that includes one or more components, such as memory devices that store data. The host system can provide data to be stored at the memory sub-system and can request data to be retrieved from the memory sub-system.

A memory sub-system can include high density non-volatile memory devices where retention of data is desired when no power is supplied to the memory device. One example of non-volatile memory devices is a not-and (NAND) memory device. Other examples of non-volatile memory devices are described below in conjunction with FIG. 1. A non-volatile memory device is a package of one or more dies. Each die can include of one or more planes. For some types of non-volatile memory devices (e.g., NAND devices), each plane includes of a set of physical blocks. Each block includes of a set of pages. Each page includes of a set of memory cells (“cells”). A cell is an electronic circuit that stores information. Depending on the cell type, a cell can store one or more bits of binary information, and has various logic states that correlate to the number of bits being stored. The logic states can be represented by binary values, such as “0” and “1,” or combinations of such values.

A memory device can include multiple memory cells arranged in a two-dimensional or a three-dimensional grid. The memory cells can be formed onto a silicon wafer in an array of columns and rows. A bitline can refer to one or more conductive lines coupled to a column of associated memory cells in a memory device. A wordline can refer to one or more conductive lines coupled to a row of associated memory cells in a memory device that are used with one or more bitlines to generate the address of each of the memory cells. The intersection of a bitline and a wordline constitutes the address of the memory cell. A block hereinafter refers to a unit of the memory device used to store data and can include a group of memory cells, a wordline group, a wordline, or individual memory cells. One or more blocks can be grouped together to form separate partitions (e.g., planes) of the memory device in order to allow concurrent operations to take place on each plane. The memory device can include circuitry that performs concurrent memory page accesses of two or more memory planes. For example, the memory device can include multiple access line driver circuits and power circuits that can be shared by the planes of the memory device to facilitate concurrent access of pages of two or more memory planes, including different page types. For case of description, these circuits can be generally referred to as independent plane driver circuits. Depending on the storage architecture employed, data can be stored across the memory planes (i.e., in stripes). Accordingly, one request to read a segment of data (e.g., corresponding to one or more data addresses), can result in read operations performed on two or more of the memory planes of the memory device.

Read disturb (RD) is a phenomenon that can occur in memory devices, where reading data from memory cells associated with a given wordline impacts the threshold voltages of memory cells associated with unselected wordlines of the same block. When reading a page from one or more memory cells, a read voltage is applied to the associated selected wordline. This voltage can cause electrons to migrate to memory cells associated with one or more other wordlines adjacent to the selected wordline unintentionally, which can compromise data integrity and cause errors during read operations since the memory cells no longer accurately represent the data they were meant to hold. If the changes in the neighboring cells are significant enough, this can lead to data corruption or bit errors in those cells. This is referred to as a “read disturb” error. The risk of read disturb increases with the number of read functions performed, which can result in read errors and higher latency from a high read error handling trigger rate.

To prevent read disturb errors, management techniques are employed. One such management technique is read disturb detection. Read disturb detection is a feature that relies on scans of the memory cells associated with randomly-selected wordlines to detect degradation from reading and screen out blocks with a certain number of memory cells suffering from read disturb. Read disturb detection can be performed through a scan (e.g., a NAND detect empty page (NDEP) scan for NAND devices), hereafter referred to as a “read disturb scan,” which is a procedure performed on the memory device to identify or measure if memory cells have been affected by read disturb. Read disturb is not the only cause of charge gain on unprogrammed memory cells and an RD scan can be applicable to other causes.

A block may comprise of one or more wordlines having associated memory cells that have been programmed (herein referred to as “programmed wordlines”) and one or more wordlines having associated memory cells that have not been intentionally programmed (herein referred to as “unprogrammed wordlines”). This block composition is herein referred to as a “partial block.”

A conventional read disturb scan may include a number of scans. For example, an unprogrammed wordline scan is a check typically performed during a read disturb scan. An unprogrammed wordline scan will check erased memory cells of a randomly-selected unprogrammed wordline for significant charge gain to prevent any future errors. Erased cells on unprogrammed wordlines, having no or minimal charge (“1”), are more susceptible to read disturb than programmed cells (on programmed wordlines), as they have a weaker electric screening effect and thus, a stronger electric field across the tunnel oxide. As a result, the erased cells on unprogrammed wordlines have a higher risk of read disturb error if they continue to be programmed. In the case of an unprogrammed wordline scan, the selected wordline will be checked to see if the number of associated memory cells with a charge (“0”) exceeds a predetermined threshold.

Some memory devices, such as three-dimensional (3D) cross-point devices, can include multiple sections. A section, such as a deck or layer, can be defined as a two-dimensional (2D) array of memory cells electronically addressable by a vertical access line(s) (e.g., wordline(s)). Multiple sections can be stacked within a memory device (e.g., stacked vertically). As the wordlines increase in layers, the likelihood of defects in the wordlines increase. The defects may include wordline-to-wordline short, and/or open wordline. For example, an open wordline indicates that a void occurs during cycling degradation and voltage signals cannot be achieved from the row decoder. This defect can occur at wordline plane, staircase connection or anywhere along the signal path. As another example, an electrical short can develop between two adjacent wordlines, and when a certain voltage, such as a program voltage, is applied to one of those wordlines, a current is developed, at least a section of which can flow through the electrical short and onto the adjacent wordline. This section of the current can be referred to as a “leakage current” and the electrical short can be referred to as a “wordline-to-wordline short.” This leakage current can impact the logical values programmed to or read from the memory cells connected to the associated wordlines leading to errors on the memory device. For example, a wordline-to-wordline short can cause a current (e.g., during a write operation applied to the selected wordline) to discharge some electrons to the wordline adjacent to the wordline being programmed. This results in the write operation failing to program data on the selected wordline, as well as the data on the adjacent wordline being corrupted.

Therefore, in some cases, some sections of the memory device have the defect that makes the sections unusable, while other sections of the memory device can still function well. For example, in a memory device that has two sections, one or more defective wordlines in one section may make the section un-useful (“defective”), while the other section still can be used to store data and can be deemed as useful (“functional”). Such a “half good” memory device may be put in use by having the defective section in an erase state. A “half good” memory device can be a memory device (or any unit of the memory device) having at least one functional section and at least one defective section. As such, it is better to maintain the defective section in an erase state. For example, if the defective section is a top section in a two-section memory device, the top section will be kept in the erase state and the bottom section will be used as normal. Thus, there is a corresponding erase scheme for the “half good” memory device, for example, so that the defective section will not be re-erased that can affect the threshold voltage distribution. For example, an erase scheme may include preprogram before applying the erase pulse to make the cells voltage more uniform after applying the erase pulse. This preprogram will apply a program pulse to all wordlines. However, for “half good” memory device, the erase scheme will not have preprogram applied on defect section as well as the erase pulse. A block can be a full block, a defective block, or a half good block (HGB). A full block refers to a block that has only functional sections. A defective block refers to a block that has only defective sections. A half good block (HGB) refers to a block that has at least one functional section and at least one defective section. In some implementations with a greater number of sections, there can even be blocks with sections that each account for a third of a full block (e.g., a “third good block” (TGB)).

In implementations, the system can combine “good” sections from multiple physical blocks to create a single “good” virtual block that can be written to as if it were a single physical block. However, there is no read disturb (RD) scan scheme to account for partially good blocks; the fragmented nature of partially good blocks presents issues for conventional RD scans. For example, in current systems, blocks comprised of HGBs and TGBs are treated as virtual blocks, subjected to the same media management algorithms as fully good blocks. However, this approach encounters challenges during read disturb scans, particularly when activated in RD scenarios within partially filled blocks. Typically, the system selects empty pages from mandatory wordlines for evaluation, but the criteria for selecting wordlines varies across different products and usage cases. For instance, during an RD scan of partially filled blocks, the system may randomly select one unprogrammed wordline from a list for checking, a process that balances the trade-off between scan coverage and latency: increasing the number of sampled wordlines enhances coverage but also incurs greater latency.

Moreover, in the cases of HGB and TGB, the RD stress is distributed directly to physical blocks rather than to the entire virtual block, resulting in uneven stress application. For example, in a scenario with partially filled blocks, the top HGB section might receive the entirety of the RD stress while the lower HGB section receives none. This uneven stress distribution can lead to a greater charge gain in the empty pages of the top HGB compared to those in the lower HGB section. The current read disturb scan algorithm can erroneously select wordlines from the lower HGB and mistakenly judge the block as “healthy for programming,” despite the empty pages in the top HGB having excessive charge gain, particularly in scenarios where the fill ratio of the virtual block is near 50% and few mandatory wordlines remain empty in the top HGB. Such inaccuracies can result in a high scan under-queue rate (e.g., scan error escape rate) which can lead to a high Bit-Error Rate (BER). This can even lead to unrecoverable error correcting code (UECC) data loss, where the number of errors is beyond the capabilities of error correcting code (ECC) operations.

Aspects of the present disclosure address the above and other deficiencies by having a memory sub-system that can account for errors in asymmetric blocks. Specifically, the system can adapt a read disturb scan flow to account for virtual blocks constructed from sections from different physical blocks of memory (hence the “asymmetric” aspect). Upon receiving a request to perform an RD scan on a partially programmed memory device block, the system evaluates whether the block is at risk of evading detection by standard RD scans due to its asymmetrical nature-namely, if it is composed of sections from different physical memory blocks. After identifying the target (e.g., high risk) section(s) of the block, the system executes RD scans on the unprogrammed wordlines of the identified section(s).

Advantages of the present disclosure include, but are not limited to, mitigating uneven RD stress in asymmetric block applications, and enhancing system performance by reducing latency due to a lower read error handling trigger rate. By effectively targeting sections at higher risk of RD and addressing errors before read operation errors occur, this approach reduces the likelihood of high BER and UECC data loss, thereby improving the reliability and efficiency of memory operations.

FIG. 1 illustrates an example computing system 100 that includes a memory sub-system 110 in accordance with some embodiments of the present disclosure. The memory sub-system 110 can include media, such as one or more volatile memory devices (e.g., memory device 140), one or more non-volatile memory devices (e.g., memory device 130), or a combination of such.

A memory sub-system 110 can be a storage device, a memory module, or a combination of a storage device and memory module. Examples of a storage device include a solid-state drive (SSD), a flash drive, a universal serial bus (USB) flash drive, an embedded Multi-Media Controller (eMMC) drive, a Universal Flash Storage (UFS) drive, a secure digital (SD) card, and a hard disk drive (HDD). Examples of memory modules include a dual in-line memory module (DIMM), a small outline DIMM (SO-DIMM), and various types of non-volatile dual in-line memory modules (NVDIMMs).

The computing system 100 can be a computing device such as a desktop computer, laptop computer, network server, mobile device, a vehicle (e.g., airplane, drone, train, automobile, or other conveyance), Internet of Things (IoT) enabled device, embedded computer (e.g., one included in a vehicle, industrial equipment, or a networked commercial device), or such computing device that includes memory and a processing device.

The computing system 100 can include a host system 120 that is coupled to one or more memory sub-systems 110. In some embodiments, the host system 120 is coupled to multiple memory sub-systems 110 of different types. FIG. 1 illustrates one example of a host system 120 coupled to one memory sub-system 110. As used herein, “coupled to” or “coupled with” generally refers to a connection between components, which can be an indirect communicative connection or direct communicative connection (e.g., without intervening components), whether wired or wireless, including connections such as electrical, optical, magnetic, etc.

The host system 120 can include a processor chipset and a software stack executed by the processor chipset. The processor chipset can include one or more cores, one or more caches, a memory controller (e.g., NVDIMM controller), and a storage protocol controller (e.g., PCIe controller, SATA controller, CXL controller). The host system 120 uses the memory sub-system 110, for example, to write data to the memory sub-system 110 and read data from the memory sub-system 110.

The host system 120 can be coupled to the memory sub-system 110 via a physical host interface. Examples of a physical host interface include, but are not limited to, a serial advanced technology attachment (SATA) interface, a compute express link (CXL) interface, a peripheral component interconnect express (PCIe) interface, universal serial bus (USB) interface, Fibre Channel, Serial Attached SCSI (SAS), a double data rate (DDR) memory bus, Small Computer System Interface (SCSI), a dual in-line memory module (DIMM) interface (e.g., DIMM socket interface that supports Double Data Rate (DDR)), etc. The physical host interface can be used to transmit data between the host system 120 and the memory sub-system 110. The host system 120 can further utilize an NVM Express (NVMe) interface to access components (e.g., memory devices 130) when the memory sub-system 110 is coupled with the host system 120 by the physical host interface (e.g., PCIe or CXL bus). The physical host interface can provide an interface for passing control, address, data, and other signals between the memory sub-system 110 and the host system 120. FIG. 1 illustrates a memory sub-system 110 as an example. In general, the host system 120 can access multiple memory sub-systems via a same communication connection, multiple separate communication connections, and/or a combination of communication connections.

The memory devices 130, 140 can include any combination of the different types of non-volatile memory devices and/or volatile memory devices. The volatile memory devices (e.g., memory device 140) can be, but are not limited to, random access memory (RAM), such as dynamic random access memory (DRAM) and synchronous dynamic random access memory (SDRAM).

Some examples of non-volatile memory devices (e.g., memory device 130) include a not-and (NAND) type flash memory and write-in-place memory, such as a three-dimensional cross-point (“3D cross-point”) memory device, which is a cross-point array of non-volatile memory cells. A cross-point array of non-volatile memory cells can perform bit storage based on a change of bulk resistance, in conjunction with a stackable cross-gridded data access array. Additionally, in contrast to many flash-based memories, cross-point non-volatile memory can perform a write in-place operation, where a non-volatile memory cell can be programmed without the non-volatile memory cell being previously erased. NAND type flash memory includes, for example, two-dimensional NAND (2D NAND) and three-dimensional NAND (3D NAND).

Each of the memory devices 130 can include one or more arrays of memory cells. One type of memory cell, for example, single level cells (SLC) can store one bit per cell. Other types of memory cells, such as multi-level cells (MLCs), triple level cells (TLCs), quad-level cells (QLCs), and penta-level cells (PLCs) can store multiple bits per cell. In some embodiments, each of the memory devices 130 can include one or more arrays of memory cells such as SLCs, MLCs, TLCs, QLCs, PLCs or any combination of such. In some embodiments, a particular memory device can include an SLC portion, and an MLC portion, a TLC portion, a QLC portion, or a PLC portion of memory cells. The memory cells of the memory devices 130 can be grouped as pages that can refer to a logical unit of the memory device used to store data. With some types of memory (e.g., NAND), pages can be grouped to form blocks.

Although non-volatile memory components such as a 3D cross-point array of non-volatile memory cells and NAND type flash memory (e.g., 2D NAND, 3D NAND) are described, the memory device 130 can be based on any other type of non-volatile memory, such as read-only memory (ROM), phase change memory (PCM), self-selecting memory, other chalcogenide based memories, ferroelectric transistor random-access memory (FeTRAM), ferroelectric random access memory (FeRAM), magneto random access memory (MRAM), Spin Transfer Torque (STT)-MRAM, conductive bridging RAM (CBRAM), resistive random access memory (RRAM), oxide based RRAM (OxRAM), not-or (NOR) flash memory, or electrically erasable programmable read-only memory (EEPROM).

A memory sub-system controller 115 (or controller 115 for simplicity) can communicate with the memory devices 130 to perform operations such as reading data, writing data, or erasing data at the memory devices 130 and other such operations. The memory sub-system controller 115 can include hardware such as one or more integrated circuits and/or discrete components, a buffer memory, or a combination thereof. The hardware can include a digital circuitry with dedicated (i.e., hard-coded) logic to perform the operations described herein. The memory sub-system controller 115 can be a microcontroller, special purpose logic circuitry (e.g., a field programmable gate array (FPGA), an application specific integrated circuit (ASIC), etc.), or other suitable processor.

The memory sub-system controller 115 can include a processing device, which includes one or more processors (e.g., processor 117), configured to execute instructions stored in a local memory 119. In the illustrated example, the local memory 119 of the memory sub-system controller 115 includes an embedded memory configured to store instructions for performing various processes, operations, logic flows, and routines that control operation of the memory sub-system 110, including handling communications between the memory sub-system 110 and the host system 120.

In some embodiments, the local memory 119 can include memory registers storing memory pointers, fetched data, etc. The local memory 119 can also include read-only memory (ROM) for storing micro-code. While the example memory sub-system 110 in FIG. 1 has been illustrated as including the memory sub-system controller 115, in another embodiment of the present disclosure, a memory sub-system 110 does not include a memory sub-system controller 115, and can instead rely upon external control (e.g., provided by an external host, or by a processor or controller separate from the memory sub-system).

In general, the memory sub-system controller 115 can receive commands or operations from the host system 120 and can convert the commands or operations into instructions or appropriate commands to achieve the desired access to the memory devices 130. The memory sub-system controller 115 can be responsible for other operations such as wear leveling operations, garbage collection operations, error detection and error-correcting code (ECC) operations, encryption operations, caching operations, and address translations between a logical address (e.g., a logical block address (LBA), namespace) and a physical address (e.g., physical block address) that are associated with the memory devices 130. The memory sub-system controller 115 can further include host interface circuitry to communicate with the host system 120 via the physical host interface. The host interface circuitry can convert the commands received from the host system into command instructions to access the memory devices 130 as well as convert responses associated with the memory devices 130 into information for the host system 120.

The memory sub-system 110 can also include additional circuitry or components that are not illustrated. In some embodiments, the memory sub-system 110 can include a cache or buffer (e.g., DRAM) and address circuitry (e.g., a row decoder and a column decoder) that can receive an address from the memory sub-system controller 115 and decode the address to access the memory devices 130.

In some embodiments, the memory devices 130 include local media controllers 135 that operate in conjunction with memory sub-system controller 115 to execute operations on one or more memory cells of the memory devices 130. An external controller (e.g., memory sub-system controller 115) can externally manage the memory device 130 (e.g., perform media management operations on the memory device 130). In some embodiments, memory sub-system 110 is a managed memory device, which is a raw memory device 130 having control logic (e.g., local media controller 135) on the die and a controller (e.g., memory sub-system controller 115) for media management within the same memory device package. An example of a managed memory device is a managed NAND (MNAND) device.

The memory sub-system 110 includes an Adaptive Scan Manager component 113 that can perform an adaptive read disturb scan for asymmetric blocks (e.g. virtual blocks). In some embodiments, the memory sub-system controller 115 includes at least a portion of the Adaptive Scan Manager component 113. In some embodiments, the Adaptive Scan Manager component 113 is part of the host system 120, an application, or an operating system. In other embodiments, local media controller 135 includes at least a portion of Adaptive Scan Manager component 113 and is configured to perform the functionality described herein.

The Adaptive Scan Manager component 113 can account for errors in asymmetric blocks. Specifically, the system can adapt a read disturb scan flow to account for virtual blocks constructed from sections from different physical blocks of memory. Upon receiving a request to perform an RD scan on a partially programmed memory device block, the system evaluates whether the block is at risk of evading detection by standard RD scans due to its asymmetrical nature-namely, if it is composed of sections from different physical memory blocks. After identifying the target (e.g., high risk) section(s) of the block, the system executes RD scans on the unprogrammed wordlines of the identified section(s). Further details with regards to the operations of the Adaptive Scan Manager component 113 are described below.

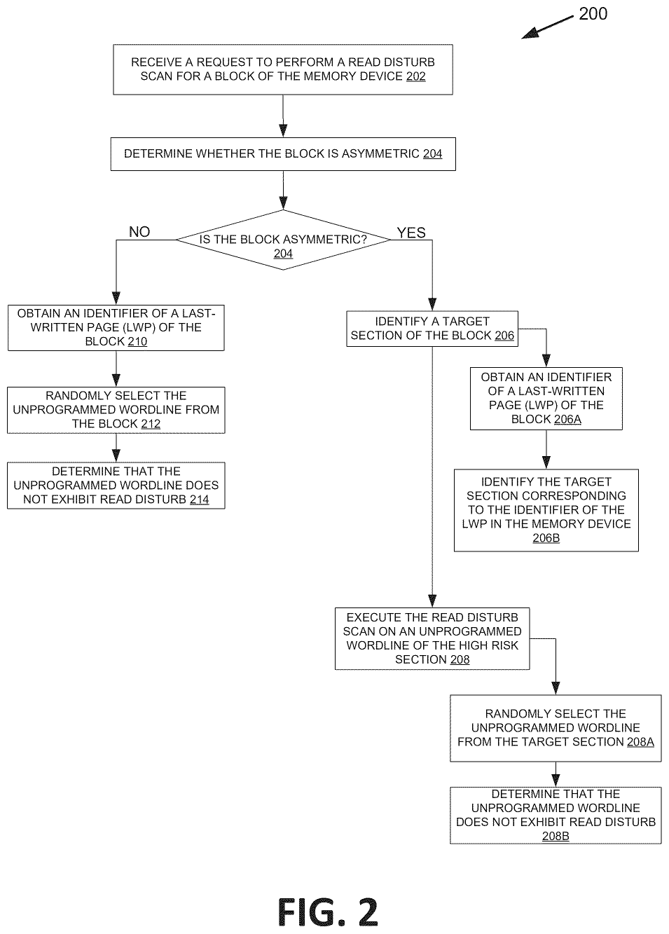

FIG. 2 is a flow diagram of an example method 200 to perform an adaptive read disturb scan on a block, in accordance with some embodiments of the present disclosure. The method 200 can be performed by processing logic that can include hardware (e.g., processing device, circuitry, dedicated logic, programmable logic, microcode, hardware of a device, integrated circuit, etc.), software (e.g., instructions run or executed on a processing device), or a combination thereof. In some embodiments, the method 200 is performed by the Adaptive Scan Manager component 113 of FIG. 1. Although shown in a particular sequence or order, unless otherwise specified, the order of the processes can be modified. Thus, the illustrated embodiments should be understood only as examples, and the illustrated processes can be performed in a different order, and some processes can be performed in parallel. Additionally, one or more processes can be omitted in various embodiments. Thus, not all processes are required in every embodiment. Other process flows are possible.

At operation 202, the processing logic receives a request to perform a read disturb scan for a block of the memory device. In embodiments, the block is partially programmed, comprising one or more wordlines having associated memory cells that have been programmed (herein referred to as “programmed wordlines”) and one or more wordlines having associated memory cells that are empty (herein referred to as “unprogrammed wordlines”). This block composition can be referred to as a “partial block.” In some embodiments, the RD scan is triggered in response to a threshold number of read operations being performed on memory device 130 in memory sub-system 110 since a previous read disturb scan was performed. In some embodiments, the RD scan is triggered in response to a read operation error.

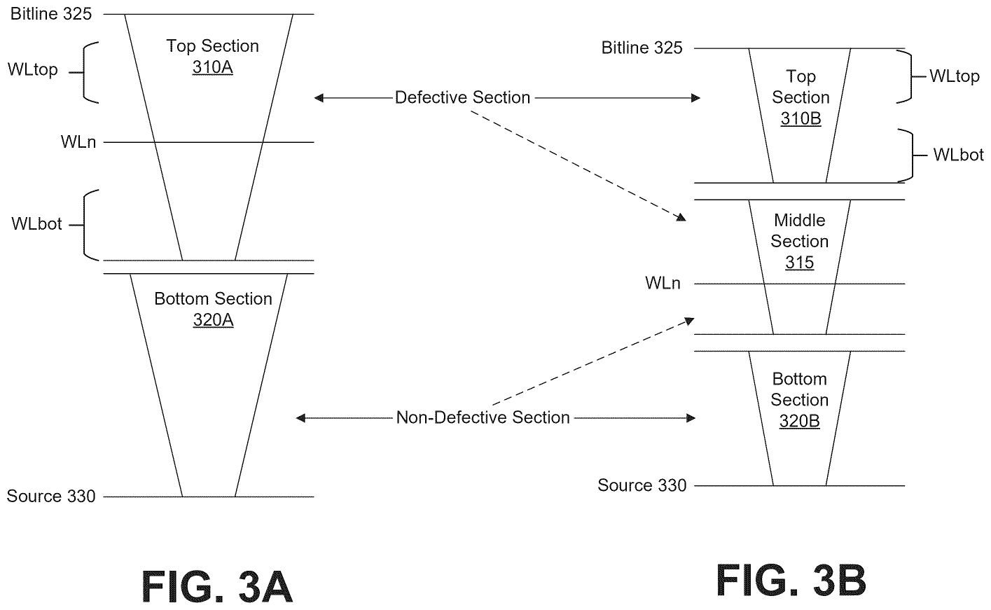

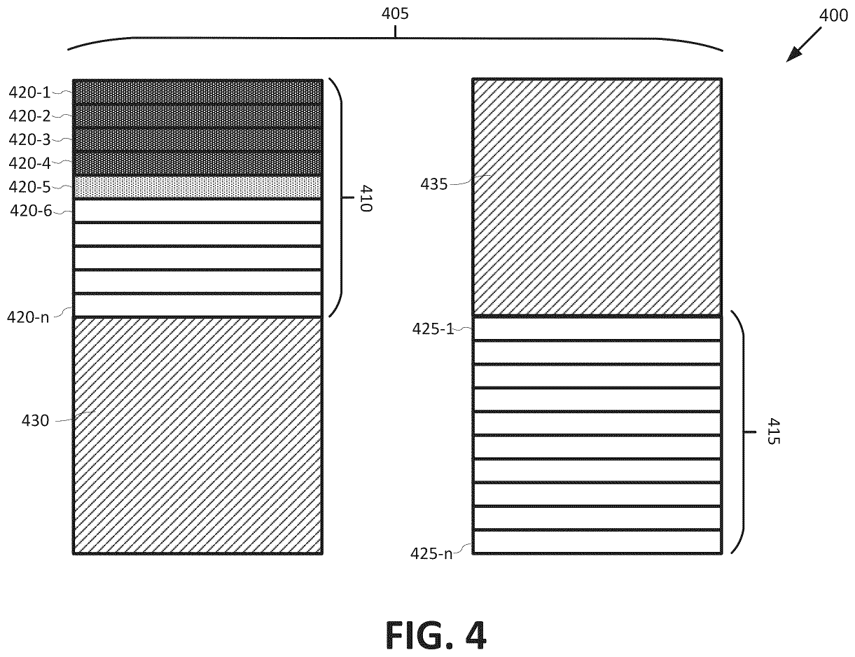

At operation 204, the processing logic determines whether the block is asymmetric. In some embodiments, a block is asymmetric if the block comprises a plurality of sections, and wherein each section comprises memory cells corresponding to a different physical block in the memory device (e.g., an asymmetric block). Each section contains a corresponding set of wordlines connected to memory cells arranged in strings. In some embodiments, the block comprises a top section and a bottom section (e.g., a HGB). In some embodiments, the block comprises a top section, a middle section, and a bottom section (e.g., a TGB). Further detail is provided with FIG. 3A and FIG. 3B.

Responsive to determining the block is asymmetric, at operation 206, the processing logic identifies a target section of the block (hereinafter referred to as a “high risk section”). In embodiments, multiple high risk sections can be identified across an asymmetric block.

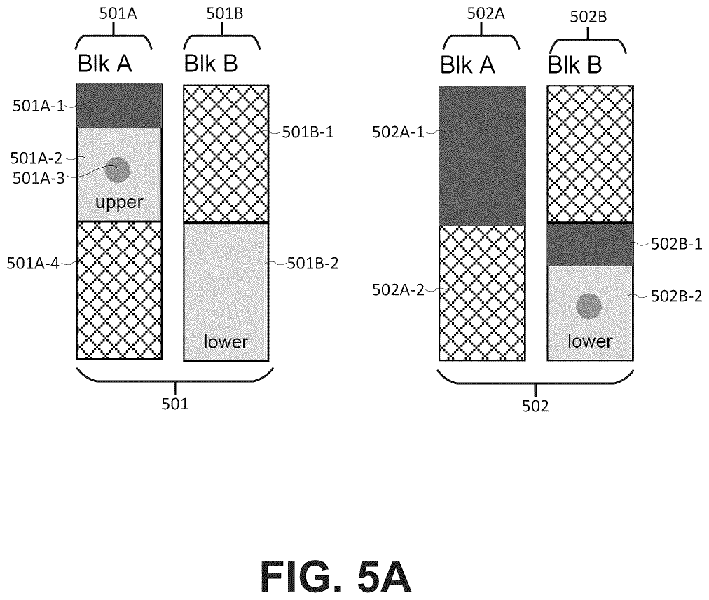

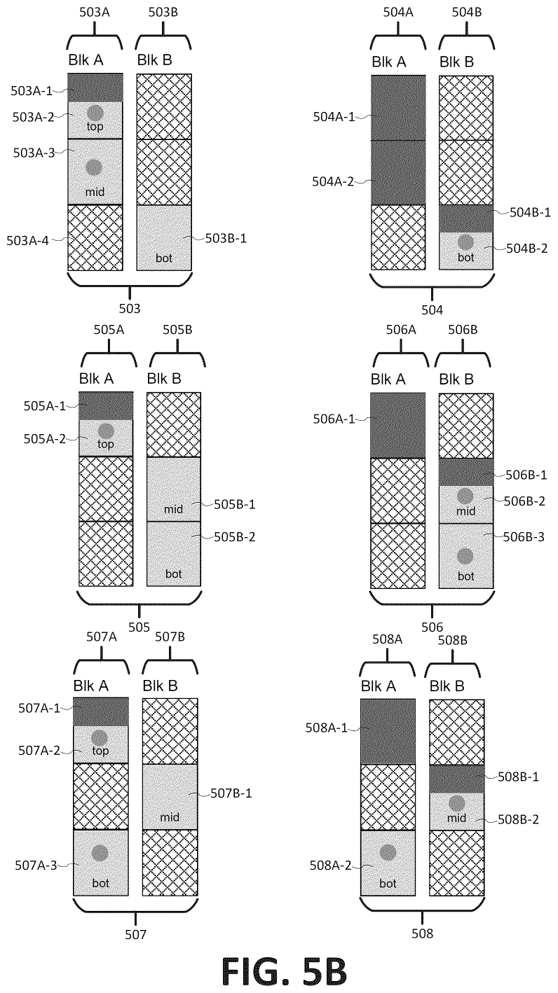

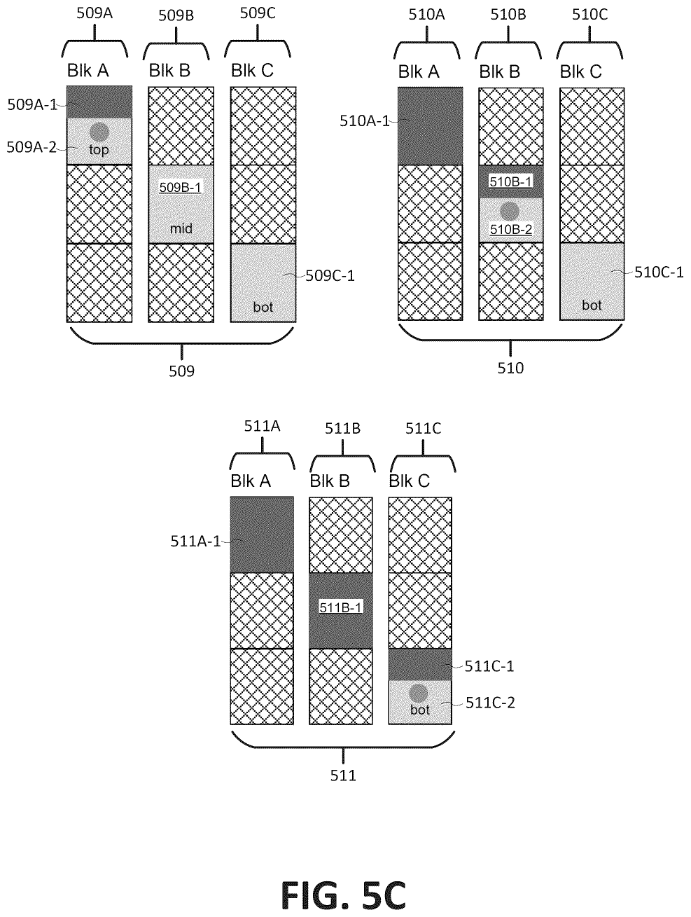

To identify one or more high risk sections of an asymmetric block, in some embodiments, at operation 206A, the processing logic obtains an identifier of a last-written page (LWP) of the block. An LWP is the most recent page within a block that has been programmed or written to. In some embodiments, the processing logic maintains the position of an LWP within the block using a corresponding identifier. At operation 206B, the processing logic identifies the high risk section corresponding to the identifier of the LWP. The high risk section is identified as the section of the partially good block in which the LWP is located. In some embodiments, sections that are subsequent to the high risk section comprising the LWP and associated with the same physical partially-good block (e.g., HGB or TGB) are also identified as high risk sections. Further detail is provided with FIG. 4 and FIGS. 5A-5C.

At operation 208, the processing logic executes the RD scan on an unprogrammed wordline of the high risk section(s) identified in operation 206. In some embodiments, to execute the RD scan on the unprogrammed wordline of the high risk section, at operation 208A, the processing logic randomly selects the unprogrammed wordline from the high risk section. With a memory device configured for sequential programming (e.g., NAND), the unprogrammed wordline follows the LWP since it has not been intentionally programmed (as opposed to unintentional programming from charge gain). In some embodiments, the unprogrammed wordline is randomly selected from a predetermined set of mandatory wordlines. In some embodiments, the predetermined set of mandatory wordlines are set at the manufacture of the memory device as part of RD scan operations.

At operation 208B, the processing logic determines that the unprogrammed wordline does not exhibit RD. A selected unprogrammed wordline is determined to not exhibit RD if it is empty (e.g., the associated memory cells do not exhibit any charge gain). If the unprogrammed wordline is not empty (e.g., exhibits charge gain), the processing logic determines the unprogrammed wordline (and by association the block) to exhibit RD.

In some embodiments, responsive to the processing logic determining that the block is not high risk (at operation 204), at operation 210, the processing logic obtains an identifier of an LWP of the block. As in operation 206, the LWP is the most recent page within a block that has been programmed or written to. In some embodiments, the processing logic maintains the position of the LWP within the block using a corresponding identifier.

At operation 212, the processing logic randomly selects the unprogrammed wordline from the block. This is in contrast to operation 208A, where the unprogrammed wordline is randomly selected from an identified high risk section. With a memory device configured for sequential programming (e.g., NAND), the unprogrammed wordline follows the LWP since it has not been intentionally programmed (as opposed to unintentional programming from charge gain). In some embodiments, the unprogrammed wordline is randomly selected from a predetermined set of mandatory wordlines. In some embodiments, the predetermined set of mandatory wordlines are set at the manufacture of the memory device as part of RD scan operations.

At operation 214, the processing logic determines that the unprogrammed wordline does not exhibit RD. A selected unprogrammed wordline is determined to not exhibit RD if it is empty (e.g., the associated memory cells do not exhibit any charge gain). If the unprogrammed wordline is not empty (e.g., exhibits charge gain), the processing logic determines the unprogrammed wordline (and by association the block) to exhibit RD.

FIG. 3A is a diagram illustrating a memory array of a bi-section memory device, in accordance with some embodiments, e.g., half-good block (HGB) programming. FIG. 3B is a diagram illustrating a memory array of a multi-section memory device (e.g., with multi-section blocks), in accordance with some embodiments, e.g., third-good block (TGB) programming. Although only two sections (i.e., a top section 310A and a bottom section 320A) are illustrated in FIG. 3A, it should be appreciated that certain memory devices can include more than two sections (e.g., three sections, four sections, and the like). For example, as shown in FIG. 3B, the memory array can include a top section 310B, a middle section 315, and a bottom section 320B. In some embodiments, each section includes a corresponding set of wordlines that are coupled to memory cells arranged in memory strings. In one embodiment, the top section 310B is arranged vertically above the middle section 315, which is arranged vertically above the bottom section 320B, such that the memory strings can extend from a drain (e.g., bitline 325) adjacent to the top section 310B, through the middle section 315, to a source (e.g., source 330) adjacent to the bottom section 320B of the memory array.

In other embodiments, there can be some other number or arrangement of sections in the memory device 130. In one embodiment, the program operation is a drain-to-source (D2S) program operation that proceeds wordline by wordline from the drain to the source within each section. Accordingly, when the memory cells associated with a selected wordline (e.g., WLn) is being programmed, the memory cells associated with wordlines in the same section and located above the selected wordline will have already been programmed, while the memory cells associated with wordlines located in the same section and below the selected wordline will not yet have been programmed. Further, according to D2S programming, the programming may also not skip programming any intervening pages. For example, if a page of data is located along a wordline that is considered defective (e.g., has a short to another wordline or other defect), this page may be programmed with a data pattern or some other dummy data. Thus, such memory devices with more than two sections may utilize a similar D2S programming algorithm and thus, face similar challenges as memory devices with two sections.

With additional reference to FIGS. 3A-3B, the embodiments referenced herein are described mostly in relation to a defective section of a block that corresponds to the top section 310A or 310B, when defective, and for TGB embodiments, the middle section 315 can also be non-defective (denoted by the dashed arrow from the “non-defective section”). In alternative TGB embodiments, however, the defective section may also include the middle section 315 when just the bottom section 320B is considered non-defective (denoted by the dashed arrow from the “defective section”). As was discussed, in the context of the present disclosure, a non-defective section of a block may be understood as corresponding to one or more bottom good sections that are closest to the substrate of a 3D memory device that has been etched with multiple sections. Further, a defective section of a block may be understood as corresponding to one or more top good sections that are located above the non-defective section, e.g., such that the non-defective section is located between the substrate and the defective section.

FIG. 4 is a diagram 400 illustrating an asymmetric block 405 with a high risk section 410, in accordance with some embodiments of the present disclosure. Diagram 400 illustrates a block that is high risk in accordance with an embodiment where the block comprises a top section and a bottom section (e.g., a virtually complete block composed of physical HGBs). As depicted, block 405 is composed of HGB sections 410 and 415. Each section comes from a physical HGB that exhibited a defect, rendering parts of the physical block defective and unusable. These defective sections are represented by sections 430 and 435. With the wordlines in the defective sections set in a constant erase state, section 410 forms the top and section 415 forms the bottom of block 405, creating a single functional virtual block of memory.

As depicted, the block 405 comprises a number of individual rows (e.g. wordlines (WL)). WLs 420-1 through 420-n represent WLs of top section 410, each having associated memory cells. WLs 425-1 through 425-n represent WLs of bottom section 415, each having associated memory cells. In top section 410, WLs 420-1 through 420-4 represent programmed WLs, each having associated memory cells that have been programmed. WLs 420-5 through 420-n represent unprogrammed WLs, each having associated memory cells that are empty. WL 420-5 represents an unprogrammed WL that is exhibiting read disturb and may pose a risk to future read and write operations. In bottom section 415, WLs 425-1 through 425-n represent unprogrammed WLs, each having associated memory cells that are empty. Because section 415 originates from a different physical section to section 410 and does not come from a partially programmed block, it is not at risk of being affected by read disturb from the partially programmed WLs in section 410.

FIGS. 5A-5C are example diagrams illustrating the identification of high risk sections in a block, in accordance with some embodiments of the present disclosure.

FIG. 5A depicts example asymmetric blocks 501 and 502, in accordance with some embodiments of the present disclosure. Asymmetric block 501 comprises partially good blocks 501A and 501B. Functional asymmetric block 501 is composed of top section 501A-2 of partially good block 501A and bottom section 501B-2 of partially good block 501B. Depicted within partially good block 501A is a top section 501A-2 and defective section 501A-4. Within section 501A-2 is written portion 501A-1, representing the pages in the partially good block 501A-2 that have been written to. Written portion 501A-1 includes the LWP to which the identifier described in operation 206A corresponds to. Partially good block 501B comprises defective section 501B-1 and a lower section 501B-2. In some embodiments, to identify the high risk section, the processing logic obtains the identifier of the LWP of the block. Determining that the identifier corresponds to section 501A-2, at operation 206, the processing logic identifies the top section of 501A, 501A-2, as a high risk section. As the partially good block of 501A is partially written to, it is at risk of read disturb. Section 501B-2 of partially good block 501B is not identified as a high risk section as there is not an LWP identifier corresponding to it (e.g., 501B is not partially written to).

Throughout FIGS. 5A-5C, a dot marker, such as that depicted by 501A-3, is present in each example to highlight sections the processing logic identifies as a high risk section.

Asymmetric block 502 comprises partially good blocks 502A and 502B. Functional asymmetric block 502 is composed of top section 502A-1 of partially good block 502A and bottom section 502B-2 of partially good block 502B. Section 502A-1 of partially good block 502A is completely written to and thus does not contain an LWP. As such, this section is not identified by the processing logic as a high risk section. Partially good block 502B is partially written to, with an LWP in section 502B-2 (as part of the written memory 502B-1). The processing logic identifies 502B-2 as a high risk section as it corresponds to the identifier of the LWP in the memory device. There is not a section of partially good block 502A that is partially written and thus section 502A-1 is not identified as a high risk section by the processing logic.

FIG. 5B depicts example asymmetric blocks 503, 504, 506, 507, and 508, in accordance with some embodiments of the present disclosure. Asymmetric block 503 comprises partially good blocks 503A and 503B. Depicted in partially good block 503A are three sections; top section 503A-2, middle section 503A-3, and bottom section 503A-4 (e.g., a TGB). Functional asymmetric block 503 is composed of top section 503A-2 and middle section 503A-3 of partially good block 503A, as well as bottom section 503B-1 of partially good block 503B. The processing logic identifies top section 503A-2 as a high risk section as it corresponds to the identifier of the LWP in the memory device (e.g., containing the LWP as part of written memory 503A-1). In accordance with some embodiments, section 503A-3 which is subsequent to the high risk section 503A-2 comprising the LWP and associated with the same physical partially-good block 503A is also identified as a high risk section. Section 503B-1 however is not identified as a high risk section as its corresponding partially good block 503B does not contain an LWP identifier (e.g., partially good block 503B is not partially written and thus does not have the same risk of RD).

Asymmetric block 504 comprises partially good blocks 504A and 504B. Sections 504A-1 and 504A-2 of partially good block 506A are completely written to and thus do not contain an LWP. As such, these sections are not identified by the processing logic as high risk sections. Partially good block 504B is partially written to, with an LWP in section 504B-2 (as part of the written memory 504B-1). The processing logic identifies 504B-2 as a high risk section as it corresponds to the identifier of the LWP in the memory device. There are no sections of partially good block 506A that are partially written and thus sections 504A-1 and 504A-2 are not identified as high risk sections by the processing logic.

Asymmetric block 505 comprises partially good blocks 505A and 505B. Partially good block 505A is partially written to, with an LWP in section 505A-2 (as part of the written memory 505A-1). The processing logic identifies 505A-2 as a high risk section as it corresponds to the identifier of the LWP in the memory device (at operation 206). There are no sections of partially good block 505B that are partially written and thus sections 505B-1 and 505B-2 are not identified as high risk sections by the processing logic.

Asymmetric block 506 comprises partially good blocks 506A and 506B. Section 506A-1 of partially good block 506A is completely written to and does not contain the LWP. As such, it is not identified by the processing logic as a high risk section. Partially good block 506B is partially written to, with an LWP in section 506B-2 (as part of the written memory 506B-1). The processing logic identifies 506B-2 as a high risk section as it corresponds to the identifier of the LWP in the memory device. In accordance with some embodiments, section 506B-3, which is subsequent to the high risk section 506B-2 comprising the LWP and associated with the same physical partially-good block 506B, is also identified as a high risk section. There are no sections of partially good block 506A that are partially written and thus section 506A-1 is not identified as a high risk section by the processing logic.

Asymmetric block 507 comprises partially good blocks 507A and 507B. Partially good block 507A is partially written to, with an LWP in section 507A-2 (as part of the written memory 507A-1). The processing logic identifies 507A-2 as a high risk section as it corresponds to the identifier of the LWP in the memory device. In accordance with some embodiments, section 507A-3 which is subsequent to the high risk section 507A-2 comprising the LWP and associated with the same physical partially-good block 507A is also identified as a high risk section. There are no sections of partially good block 507B that are partially written and thus section 507B-1 is not identified as a high risk section by the processing logic.

Asymmetric block 508 comprises partially good blocks 508A and 508B. Partially good block 508B is partially written to, with an LWP in section 508B-2 (as part of the written memory 508B-1). The processing logic identifies middle section 508B-2 as a high risk section as it corresponds to the identifier of the LWP in the memory device. There are no sections of partially good block 508A that are partially written and thus top section 508A-1 and bottom section 508A-2 are not identified as high risk sections by the processing logic.

FIG. 5C depicts example asymmetric blocks 509, 510, and 511, in accordance with some embodiments of the present disclosure. Asymmetric blocks 509, 510, and 511 are examples of embodiments where the block comprises a top section, a middle section, and a bottom section (e.g., TGBs). Asymmetric block 509 comprises partially good blocks 509A, 509B, and 509C.

Functional asymmetric block 509 is composed of top section 509A-2 of partially good block 509A, middle section 509B-1 of partially good block 509B, and bottom section 509C-1 of partially good block 509C. The processing logic identifies top section 509A-2 as a high risk section as it corresponds to the identifier of the LWP in the memory device (e.g., containing the LWP as part of written memory 509A-1). There are no sections of partially good block 509B or 509C that are partially written, and thus middle section 509B-1 and bottom section 509C-1 are not identified as high risk sections by the processing logic.

Asymmetric block 510 comprises partially good blocks 510A, 510B, and 510C. Functional asymmetric block 510 is composed of top section 510A-1 of partially good block 510A, middle section 510B-2 of partially good block 510B, and bottom section 510C-1 of partially good block 510C. The processing logic identifies middle section 510B-2 as a high risk section as it corresponds to the identifier of the LWP in the memory device (e.g., containing the LWP as part of written memory 510B-1). There are no sections of partially good block 510A or 510C that are partially written, and thus top section 510A-1 and bottom section 510C-1 are not identified as high risk sections by the processing logic.

Asymmetric block 511 comprises partially good blocks 511A, 511B, and 511C. Functional asymmetric block 511 is composed of top section 511A-1 of partially good block 511A, middle section 511B-1 of partially good block 511B, and bottom section 511C-2 of partially good block 511C. The processing logic identifies bottom section 511C-2 as a high risk section as it corresponds to the identifier of the LWP in the memory device (e.g., containing the LWP as part of written memory 511C-1). There are no sections of partially good block 511A or 511B that are partially written, and thus top section 511A-1 and bottom section 511B-1 are not identified as high risk sections by the processing logic.

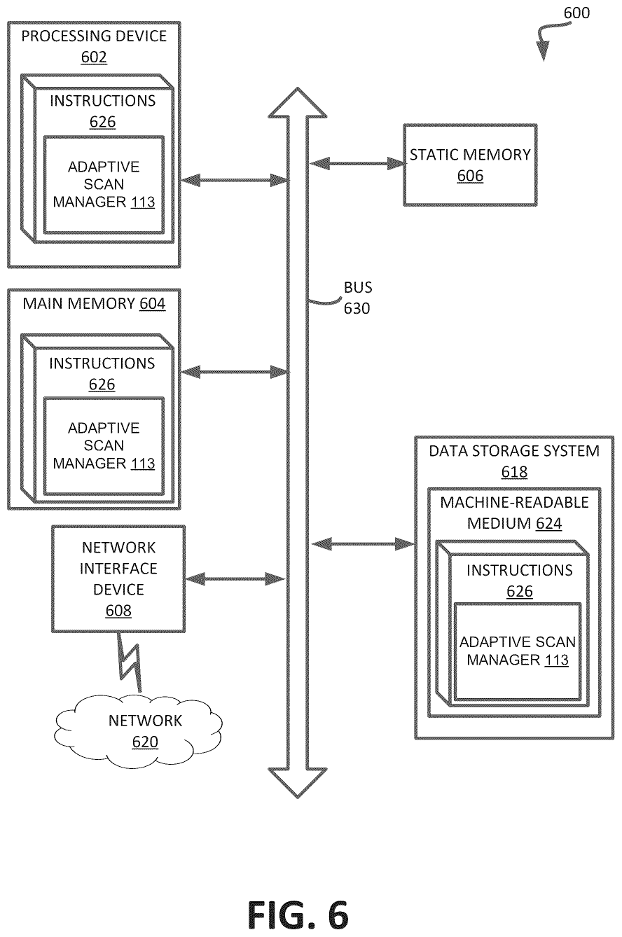

FIG. 6 illustrates an example machine of a computer system 600 within which a set of instructions, for causing the machine to perform any one or more of the methodologies discussed herein, can be executed. In some embodiments, the computer system 600 can correspond to a host system (e.g., the host system 120 of FIG. 1) that includes, is coupled to, or utilizes a memory sub-system (e.g., the memory sub-system 110 of FIG. 1) or can be used to perform the operations of a controller (e.g., to execute an operating system to perform operations corresponding to the Adaptive Scan Manager component 113 of FIG. 1). In alternative embodiments, the machine can be connected (e.g., networked) to other machines in a LAN, an intranet, an extranet, and/or the Internet. The machine can operate in the capacity of a server or a client machine in a client-server network environment, as a peer machine in a peer-to-peer (or distributed) network environment, or as a server or a client machine in a cloud computing infrastructure or environment.

The machine can be a personal computer (PC), a tablet PC, a set-top box (STB), a Personal Digital Assistant (PDA), a cellular telephone, a web appliance, a server, a network router, a switch or bridge, or any machine capable of executing a set of instructions (sequential or otherwise) that specify actions to be taken by that machine. Further, while a single machine is illustrated, the term “machine” shall also be taken to include any collection of machines that individually or jointly execute a set (or multiple sets) of instructions to perform any one or more of the methodologies discussed herein.

The example computer system 600 includes a processing device 602, a main memory 604 (e.g., read-only memory (ROM), flash memory, dynamic random access memory (DRAM) such as synchronous DRAM (SDRAM) or RDRAM, etc.), a static memory 606 (e.g., flash memory, static random access memory (SRAM), etc.), and a data storage system 618, which communicate with each other via a bus 630.

Processing device 602 represents one or more general-purpose processing devices such as a microprocessor, a central processing unit, or the like. More particularly, the processing device can be a complex instruction set computing (CISC) microprocessor, reduced instruction set computing (RISC) microprocessor, very long instruction word (VLIW) microprocessor, or a processor implementing other instruction sets, or processors implementing a combination of instruction sets. Processing device 602 can also be one or more special-purpose processing devices such as an application specific integrated circuit (ASIC), a field programmable gate array (FPGA), a digital signal processor (DSP), network processor, or the like. The processing device 602 is configured to execute instructions 626 for performing the operations and steps discussed herein. The computer system 600 can further include a network interface device 608 to communicate over the network 620.

The data storage system 618 can include a machine-readable storage medium 624 (also known as a computer-readable medium) on which is stored one or more sets of instructions 626 or software embodying any one or more of the methodologies or functions described herein. The instructions 626 can also reside, completely or at least partially, within the main memory 604 and/or within the processing device 602 during execution thereof by the computer system 600, the main memory 604 and the processing device 602 also constituting machine-readable storage media. The machine-readable storage medium 624, data storage system 618, and/or main memory 604 can correspond to the memory sub-system 110 of FIG. 1.

In one embodiment, the instructions 626 include instructions to implement functionality corresponding to an Adaptive Scan Manager component (e.g., the Adaptive Scan Manager component 113 of FIG. 1). While the machine-readable storage medium 624 is shown in an example embodiment to be a single medium, the term “machine-readable storage medium” should be taken to include a single medium or multiple media that store the one or more sets of instructions. The term “machine-readable storage medium” shall also be taken to include any medium that is capable of storing or encoding a set of instructions for execution by the machine and that cause the machine to perform any one or more of the methodologies of the present disclosure. The term “machine-readable storage medium” shall accordingly be taken to include, but not be limited to, solid-state memories, optical media, and magnetic media.

Some portions of the preceding detailed descriptions have been presented in terms of algorithms and symbolic representations of operations on data bits within a computer memory. These algorithmic descriptions and representations are the ways used by those skilled in the data processing arts to most effectively convey the substance of their work to others skilled in the art. An algorithm is here, and generally, conceived to be a self-consistent sequence of operations leading to a desired result. The operations are those requiring physical manipulations of physical quantities. Usually, though not necessarily, these quantities take the form of electrical or magnetic signals capable of being stored, combined, compared, and otherwise manipulated. It has proven convenient at times, principally for reasons of common usage, to refer to these signals as bits, values, elements, symbols, characters, terms, numbers, or the like.

It should be borne in mind, however, that all of these and similar terms are to be associated with the appropriate physical quantities and are merely convenient labels applied to these quantities. The present disclosure can refer to the action and processes of a computer system, or similar electronic computing device, that manipulates and transforms data represented as physical (electronic) quantities within the computer system's registers and memories into other data similarly represented as physical quantities within the computer system memories or registers or other such information storage systems.

The present disclosure also relates to an apparatus for performing the operations herein. This apparatus can be specially constructed for the intended purposes, or it can include a general purpose computer selectively activated or reconfigured by a computer program stored in the computer. Such a computer program can be stored in a computer readable storage medium, such as, but not limited to, any type of disk including floppy disks, optical disks, CD-ROMs, and magnetic-optical disks, read-only memories (ROMs), random access memories (RAMs), EPROMS, EEPROMs, magnetic or optical cards, or any type of media suitable for storing electronic instructions, each coupled to a computer system bus.

The algorithms and displays presented herein are not inherently related to any particular computer or other apparatus. Various general purpose systems can be used with programs in accordance with the teachings herein, or it can prove convenient to construct a more specialized apparatus to perform the method. The structure for a variety of these systems will appear as set forth in the description below. In addition, the present disclosure is not described with reference to any particular programming language. It will be appreciated that a variety of programming languages can be used to implement the teachings of the disclosure as described herein.

The present disclosure can be provided as a computer program product, or software, that can include a machine-readable medium having stored thereon instructions, which can be used to program a computer system (or other electronic devices) to perform a process according to the present disclosure. A machine-readable medium includes any mechanism for storing information in a form readable by a machine (e.g., a computer). In some embodiments, a machine-readable (e.g., computer-readable) medium includes a machine (e.g., a computer) readable storage medium such as a read only memory (“ROM”), random access memory (“RAM”), magnetic disk storage media, optical storage media, flash memory components, etc.

In the foregoing specification, embodiments of the disclosure have been described with reference to specific example embodiments thereof. It will be evident that various modifications can be made thereto without departing from the broader spirit and scope of embodiments of the disclosure as set forth in the following claims. The specification and drawings are, accordingly, to be regarded in an illustrative sense rather than a restrictive sense.

What is claimed is:

1. A system, comprising:
a memory device; and
a processing device, operatively coupled with the memory device, to perform operations comprising:
receiving a request to perform a read disturb scan for a block of the memory device, wherein the block is partially programmed;
determining whether the block is asymmetric;
responsive to determining the block is asymmetric, identifying a target section of the block; and
executing the read disturb scan on an unprogrammed wordline of the target section.

2. The system of claim 1, wherein the block determined to be asymmetric comprises a plurality of sections, and wherein each section comprises memory cells corresponding to a different physical block in the memory device.

3. The system of claim 1, wherein the block comprises a top section and a bottom section.

4. The system of claim 1, wherein the block comprises a top section, a middle section, and a bottom section.

5. The system of claim 1, wherein identifying the target section of the block comprises:
obtaining an identifier of a last-written page (LWP) of the block; and
identifying the target section corresponding to the identifier of the LWP in the memory device.

6. The system of claim 5, wherein executing the read disturb scan on the unprogrammed wordline of the target section comprises:
randomly selecting the unprogrammed wordline from the target section, wherein the unprogrammed wordline follows the LWP; and
determining that the unprogrammed wordline does not exhibit read disturb.

7. The system of claim 6, wherein the unprogrammed wordline is randomly selected from a predetermined set of mandatory wordlines.

8. The system of claim 1, further comprising:
responsive to determining that the block is not asymmetric, obtaining an identifier of a last-written page (LWP) of the block;
randomly selecting the unprogrammed wordline from the block, wherein the unprogrammed wordline follows the LWP; and
determining that the unprogrammed wordline does not exhibit read disturb.

9. A method, comprising:
receiving a request to perform a read disturb scan for a block of a memory device, wherein the block is partially programmed;
determining whether the block is asymmetric;
responsive to determining the block is asymmetric, identifying a target section of the block; and
executing the read disturb scan on an unprogrammed wordline of the target section.

10. The method of claim 9, wherein the block determined to be asymmetric comprises a plurality of sections, and wherein each section comprises memory cells corresponding to a different physical block in the memory device.

11. The method of claim 9, wherein the block comprises a top section and a bottom section.

12. The method of claim 9, wherein the block comprises a top section, a middle section, and a bottom section.

13. The method of claim 9, wherein identifying the target section of the block comprises:
obtaining an identifier of a last-written page (LWP) of the block; and
identifying the target section corresponding to the identifier of the LWP in the memory device.

14. The method of claim 13, wherein executing the read disturb scan on the unprogrammed wordline of the target section comprises:
randomly selecting the unprogrammed wordline from the target section, wherein the unprogrammed wordline follows the LWP; and
determining that the unprogrammed wordline does not exhibit read disturb.

15. The method of claim 14, wherein the unprogrammed wordline is randomly selected from a predetermined set of mandatory wordlines.

16. The method of claim 9, further comprising:
responsive to determining that the block is not asymmetric, obtaining an identifier of a last-written page (LWP) of the block;
randomly selecting the unprogrammed wordline from the block, wherein the unprogrammed wordline follows the LWP; and
determining that the unprogrammed wordline does not exhibit read disturb.

17. A non-transitory computer-readable storage medium comprising instructions that, when executed by a processing device, cause the processing device to perform operations comprising:
receiving a request to perform a read disturb scan for a block of a memory device, wherein the block is partially programmed;
determining whether the block is asymmetric;
responsive to determining the block is asymmetric, identifying a target section of the block; and
executing the read disturb scan on an unprogrammed wordline of the target section.

18. The non-transitory computer-readable storage medium of claim 17, wherein the block determined to be asymmetric comprises a plurality of sections, and wherein each section comprises memory cells corresponding to a different physical block in the memory device.

19. The non-transitory computer-readable storage medium of claim 17, wherein identifying the target section of the block comprises:
obtaining an identifier of a last-written page (LWP) of the block; and
identifying the target section corresponding to the identifier of the LWP in the memory device.

20. The non-transitory computer-readable storage medium of claim 17, further comprising:
responsive to determining that the block is not target, obtaining an identifier of a last-written page (LWP) of the block;
randomly selecting the unprogrammed wordline from the block, wherein the unprogrammed wordline follows the LWP; and
determining that the unprogrammed wordline does not exhibit read disturb.
